(19) United States
(12) Patent Application Publication
(10) Pub. No.: US 2023/0216481 A1
(43) Pub. Date: Jul. 6, 2023

(54) ACOUSTIC RESONATOR PACKAGE

(71) Applicant: SAMSUNG ELECTRO-MECHANICS CO., LTD., Suwon-si (KR)

(72) Inventor: Jung Woo SUNG, Suwon-si (KR)

(73) Assignee: SAMSUNG ELECTRO-MECHANICS CO., LTD., Suwon-si (KR)

(21) Appl. No.: 17/992,151

(22) Filed: Nov. 22, 2022

(30) Foreign Application Priority Data
Dec. 31, 2021 (KR) 10-2021-0194079

(51) Int. Cl. H03H 9/205; H03H 9/13; H03H 9/56

(52) U.S. Cl. CPC H03H 9/205; H03H 9/13; H03H 9/568

(57) ABSTRACT

An acoustic resonator package is provided. The acoustic resonator package includes a substrate, a cap, a plurality of acoustic resonators disposed between the substrate and the cap and configured to be electrically connected to each other, a grounding member disposed between the substrate and the cap, and a breakdown voltage shortener configured to provide an air gap to shorten a breakdown voltage between one of the plurality of acoustic resonators and the grounding member.

### CROSS-REFERENCE TO RELATED APPLICATIONS

This application claims the benefit under 35 USC § 119(a) of Korean Patent Application No. 10-2021-0194079, filed on Dec. 31, 2021, in the Korean Intellectual Property Office, the entire disclosure of which is incorporated herein by reference for all purposes.

### BACKGROUND

### 1. Field

The following description relates to an acoustic resonator package.

### 2. Description of Related Art

With the recent rapid development of mobile communications devices, chemical and biological testing devices, and the like, the demand for small and lightweight filters, oscillators, resonant elements, acoustic resonant mass sensors, and the like, implemented in these devices has increased.

Bulk acoustic resonators may be configured as devices that implement such small and lightweight filters, oscillators, resonator elements, and acoustic resonant mass sensors, and may have a very small form factor while having high performance, as compared to dielectric filters, metal cavity filters, wave guides, and the like, so that bulk acoustic resonators are widely used in communications modules of modern mobile devices that require high performance (e.g., high quality factor, low energy loss, and wide pass bandwidth).

Recently, the wavelengths of radio frequency (RF) signals used in communication devices have been gradually shortened, a size of an acoustic resonator or an acoustic resonator package including the same has also gradually decreased. Additionally, as the wavelengths of RF signals are shorter, a greater amount of power may be desirous in a transmission and/or reception process.

### SUMMARY

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

In a general aspect, an acoustic resonator package includes a substrate; a cap; a plurality of acoustic resonators disposed between the substrate and the cap, and configured to be electrically connected to each other; a grounding member disposed between the substrate and the cap; and a breakdown voltage shortener configured to provide an air gap to shorten a breakdown voltage between one of the plurality of acoustic resonators and the grounding member.

A width of the air gap may be greater than 0 µm and less than or equal to 20 µm.

The breakdown voltage shortener may include a portion that protrudes from the grounding member or a portion that protrudes toward the grounding member, and a width of the air gap may be narrower than a length of the air gap perpendicular to the width.

The breakdown voltage shortener may include a first portion that protrudes toward the grounding member and a second portion that protrudes from the grounding member, and the air gap may be located between the first portion and the second portion.

The grounding member may be configured to provide a coupling force between the substrate and the cap.

An outer portion of the substrate may be located closer to the grounding member than to the plurality of acoustic resonators.

The grounding member may be configured to surround the plurality of acoustic resonators, and another of the plurality of acoustic resonators may be electrically connected to a ground port disposed at a position that is different from a position of the grounding member.

Each of the plurality of acoustic resonators may be a bulk acoustic resonator which has a structure in which a first electrode, a piezoelectric layer, and a second electrode are stacked in a direction in which the substrate and the cap face each other, and the plurality of acoustic resonators are configured to form a frequency bandwidth of a filter.

The acoustic resonator package may further include a first radio frequency (RF) port and a second RF port electrically connected to the one of the plurality of acoustic resonators to pass an external RF signal of the acoustic resonator package between at least one of the plurality of acoustic resonators, wherein the breakdown voltage shortener may be configured to shorten a breakdown voltage between one of the first RF port and the second RF port and the grounding member.

The breakdown voltages of the first RF port and the second RF port for the grounding member may be different from each other.

The breakdown voltage shortener may include a first portion that protrudes from one of the first RF port and the second RF port toward the grounding member.

The breakdown voltage shortener may further include a second portion that protrudes from the grounding member toward one of the first RF port and the second RF port, and a width of at least a portion of at least one of the first portion and the second portion becomes narrower in a direction toward the air gap.

In a general aspect, an acoustic resonator package includes a substrate; a cap; a plurality of acoustic resonators disposed between the substrate and the cap and configured to be electrically connected to each other; a grounding member disposed between the substrate and the cap; and a breakdown voltage shortener configured to shorten a breakdown voltage between one of the plurality of acoustic resonators and the grounding member; wherein the breakdown voltage shortener comprises a portion that protrudes to have a width that narrows in a direction extending from the grounding member, or that protrudes to have a width that narrows in a direction toward the grounding member.

The acoustic resonator package may further include a first radio frequency (RF) port and a second RF port that are electrically connected to one of the plurality of acoustic resonators to pass an external RF signal of the acoustic resonator package between at least one of the plurality of acoustic resonators, wherein the breakdown voltage shortener comprises the portion that protrudes to have a width that narrows in the direction from the grounding member, or a portion that protrudes to have a width that narrows in a direction from one of the first RF port and the second RF port to the grounding member.

The breakdown voltages of the first RF port and the second RF port for the grounding member may be different from each other.

An outer portion of the substrate may be located closer to the grounding member than to the plurality of acoustic resonators, and another of the plurality of acoustic resonators may be electrically connected to a ground port disposed at a position that is different from a position of the grounding member.

The grounding member may be configured to provide a coupling force between the substrate and the cap.

Each of the plurality of acoustic resonators may be a bulk acoustic resonator having a structure in which a first electrode, a piezoelectric layer, and a second electrode are stacked in a direction in which the substrate and the cap face each other, and the plurality of acoustic resonators may be configured to form a frequency bandwidth of a filter.

In a general aspect, an acoustic resonator package includes a substrate; a cap; a plurality of acoustic resonators disposed between the substrate and the cap, and configured to be electrically connected to each other; grounding member, comprising a plurality of conductive rings, and disposed between the substrate and the cap; and a breakdown voltage shortener configured to shorten a breakdown voltage between one of the plurality of acoustic resonators and the grounding member; wherein the breakdown voltage shortener is disposed adjacent to the grounding member.

The breakdown voltage shortener comprises a first portion that extends in a direction from one of a first RF port and a second RF port to the grounding member, and a second portion that extends in a direction from the grounding member to the one of the first RF port and the second RF port.

Other features and aspects will be apparent from the following detailed description, the drawings, and the claims.

### BRIEF DESCRIPTION OF DRAWINGS

FIG. 1A and FIG. 1B are circuit diagrams illustrating an example acoustic resonator filter that may be included in an acoustic resonator package, in accordance with one or more embodiments.

FIG. 2A, FIG. 2B, FIG. 2C, FIG. 2D, and FIG. 2E are plan views illustrating various types of breakdown voltage shorteners that may be included in an example acoustic resonator package from the perspective of the cap toward the substrate, in accordance with one or more embodiments.

FIG. 3 is a plan view illustrating various positions and numbers of breakdown voltage shorteners that may be included in an example acoustic resonator package, in accordance with one or more embodiments.

FIG. 4 is a plan view illustrating a large-capacity structure of an example acoustic resonator package, in accordance with one or more embodiments.

FIG. 5A and FIG. 5B are perspective views illustrating an example acoustic resonator package, in accordance with one or more embodiments.

FIG. 6A is a plan view illustrating a specific structure of an example acoustic resonator that may be included in an example acoustic resonator package, in accordance with one or more embodiments.

FIG. 6B is a cross-sectional view taken along line I-I′ of FIG. 6A.

FIG. 6C is a cross-sectional view taken along line II-II′ of FIG. 6A.

FIG. 6D is a cross-sectional view taken along line III-III′ of FIG. 6A.

FIG. 6E and FIG. 6F are cross-sectional views illustrating a structure for electrically connecting the inside and the outside of an example acoustic resonator package, in accordance with one or more embodiments.

FIG. 7A and FIG. 7B are cross-sectional views illustrating a bonding structure between a cap and a base substrate of an example acoustic resonator package, in accordance with one or more embodiments.

Throughout the drawings and the detailed description, the same reference numerals may refer to the same, or like, elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known, after an understanding of the disclosure of this application, may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. Likewise, expressions, for example, “between” and “immediately between” and “adjacent to” and “immediately adjacent to” may also be construed as described in the foregoing.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof. The use of the term “may” herein with respect to an example or embodiment (for example, as to what an example or embodiment may include or implement) means that at least one example or embodiment exists where such a feature is included or implemented, while all examples are not limited thereto.

Unless otherwise defined, all terms, including technical and scientific terms, used herein have the same meaning as commonly understood by one of ordinary skill in the art to which this disclosure pertains consistent with and after an understanding of the present disclosure. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

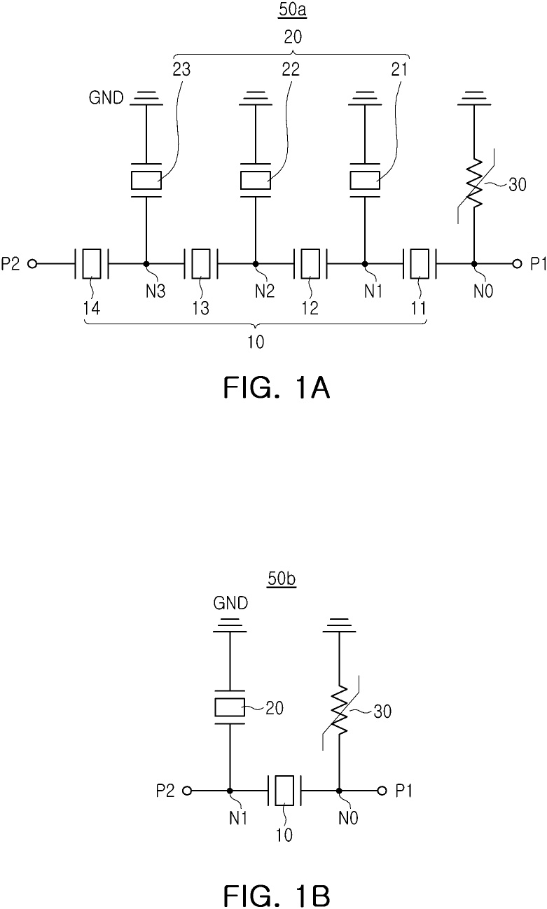

FIGS. 1A and 1B are circuit diagrams illustrating an example acoustic resonator filter that may be included in an acoustic resonator package, in accordance with one or more embodiments.

Referring to FIGS. 1A and 1B, acoustic resonator filters 50a and 50b that may be included in an example acoustic resonator package, in accordance with one or more embodiments, may include a series unit 10 and a shunt unit 20, and may allow a radio frequency (RF) signal to pass or to be blocked between a first RF port P1 and a second RF port P2 according to a frequency of the RF signal. The first and second RF ports P1 and P2 may be electrically connected to at least one series acoustic resonator 11, 12, 13, and 14 so that an external RF signal of the acoustic resonator package may pass through the at least one series acoustic resonator 11, 12, 13, and 14.

The series unit 10 may include at least one series acoustic resonator 11, 12, 13, and 14, and the shunt unit 20 may include at least one shunt acoustic resonator 21, 22, and 23.

In an example, a plurality of nodes N1, N2, and N3 between the at least one series acoustic resonator 11, 12, 13, and 14, between the at least one shunt acoustic resonator 21, 22, and 23, and between the series unit 10 and the shunt unit 20 may be implemented as a metal layer. The metal layer may be implemented with a material having a relatively low resistivity, such as, but not limited to, gold (Au), gold-tin (Au—Sn) alloy, copper (Cu), copper-tin (Cu—Sn) alloy, aluminum (Al), aluminum alloy, and the like, but the one or more examples are not limited thereto.

Each of the at least one series acoustic resonator 11, 12, 13, and 14 and the at least one shunt acoustic resonator 21, 22, and 23 may convert and inversely convert electrical energy of an RF signal into mechanical energy through piezoelectric properties, and as a frequency of the RF signal is closer to a resonant frequency of the acoustic resonator, an energy transfer rate between a plurality of electrodes may be significantly increased, and as a frequency of the RF signal is closer to an antiresonant frequency of the acoustic resonator, the energy transfer rate between the plurality of electrodes may be significantly lowered. The antiresonant frequency of the acoustic resonator may be higher than the resonant frequency of the acoustic resonator.

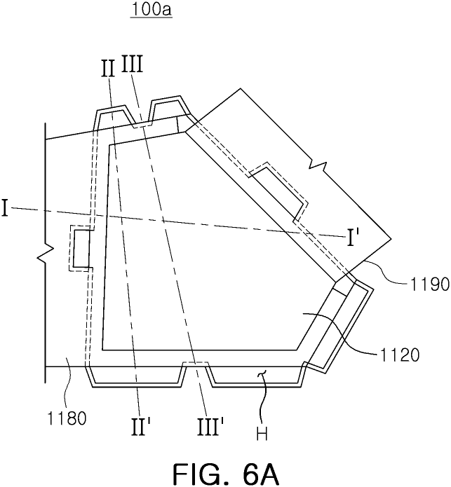

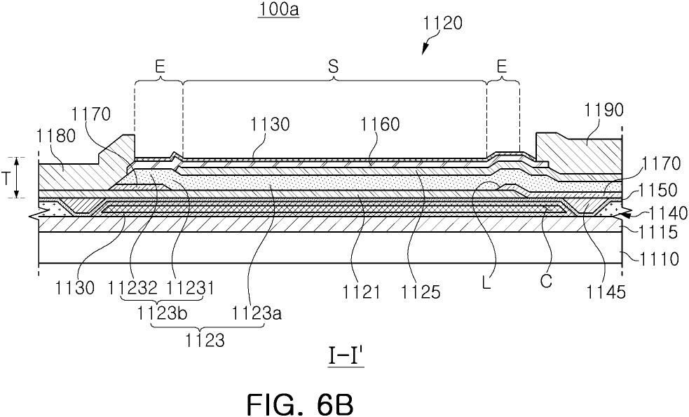

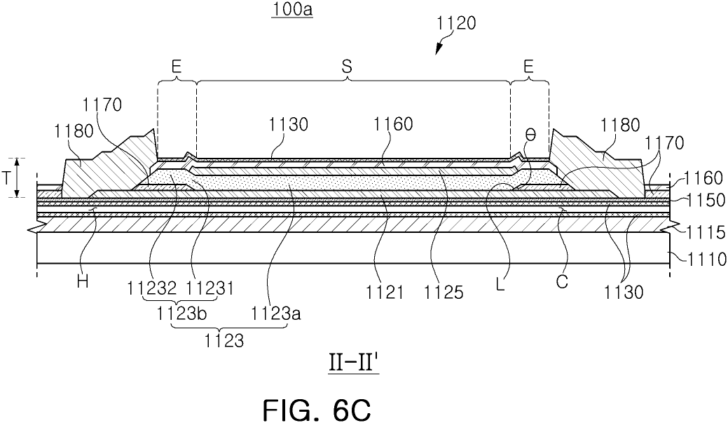

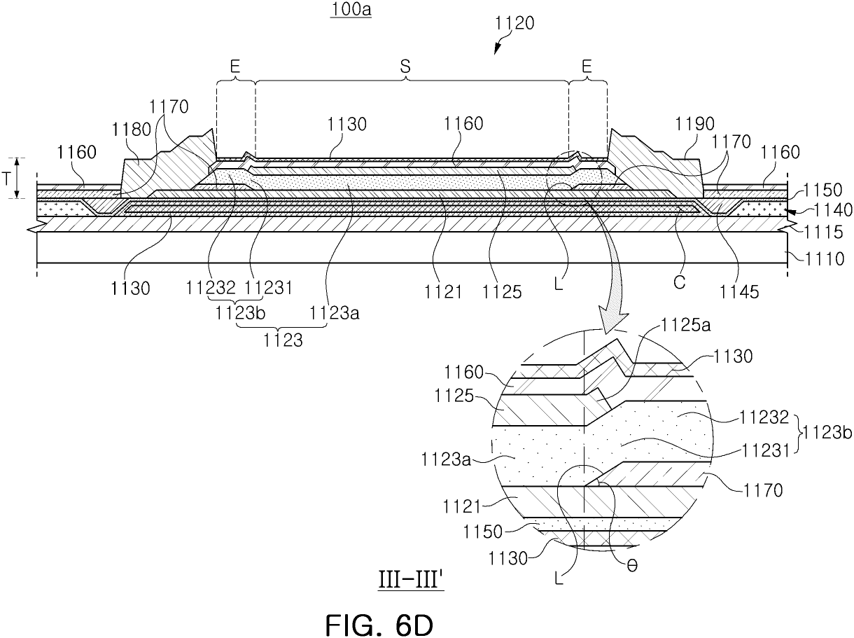

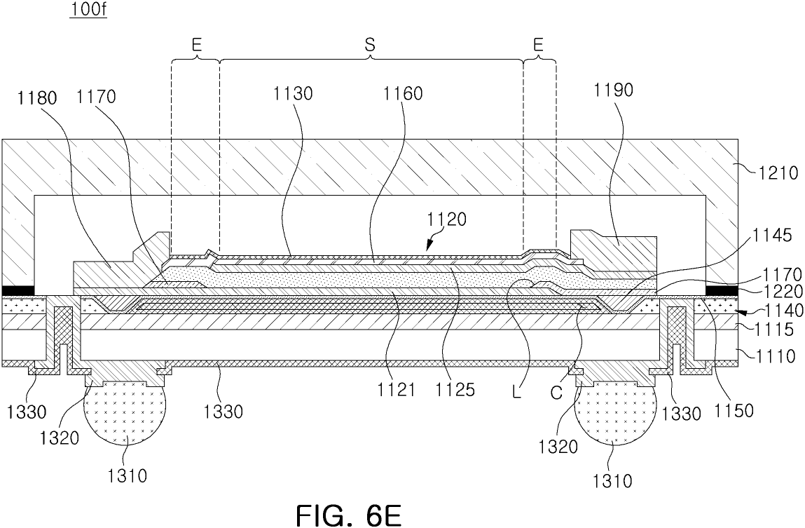

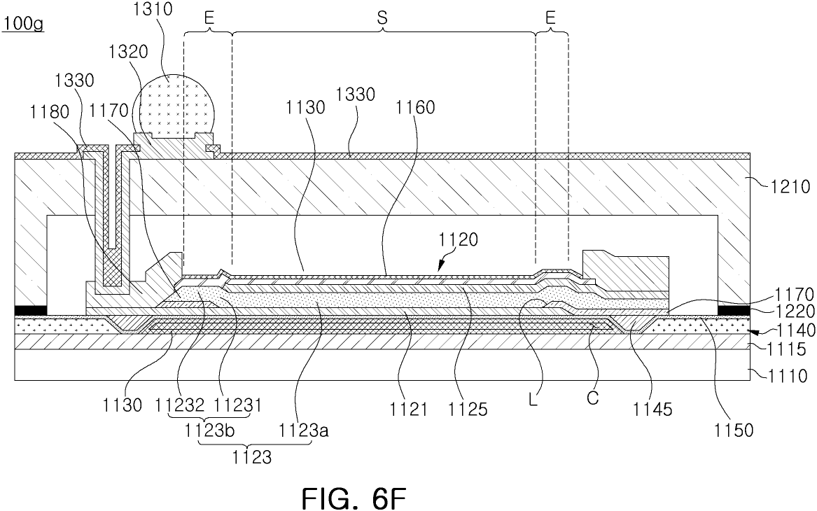

For example, each of the at least one series acoustic resonator 11, 12, 13, and 14 and the at least one shunt acoustic resonator 21, 22, and 23 may be a bulk acoustic resonator or a surface acoustic resonator, and the bulk acoustic resonator (refer to FIGS. 6A to 6F) may be a film bulk acoustic resonator (FBAR) or a solidly mounted resonator (SMR) type resonator.

At least one series acoustic resonator 11, 12, 13, and 14 may be electrically connected between the first and second RF ports P1 and P2 in series, and as the frequency of the RF signal is close to the resonant frequency, a pass rate of the RF signal between the first and second RF ports P1 and P2 may increase, and as the frequency of the RF signal is close to an antiresonant frequency, the pass rate of the RF signal between the first and second RF ports P1 and P2 may decrease.

The at least one shunt acoustic resonator 21, 22, and 23 may be electrically shunt-connected between the at least one series acoustic resonator 11, 12, 13, and 14 and a ground port GND, as the frequency of the RF signal is close to the resonant frequency, a pass rate of the RF signal toward the ground port GND may increase, and as the frequency of the RF signal is close to the antiresonant frequency, the pass rate of the RF signal toward the ground port GND may decrease.

The pass rate of the RF signal between the first and second RF ports P1 and P2 may decrease as the pass rate of the RF signal toward the ground port GND is higher, and may increase as the pass rate of the RF signal toward the ground port GND is lower.

That is, the pass rate of the RF signal between the first and second RF ports P1 and P2 may decrease as the frequency of the RF signal is close to the resonant frequency of the at least one shunt acoustic resonator 21, 22, and 23 or close to the antiresonant frequency of the at least one series acoustic resonator 11, 12, 13 and 14.

Since the antiresonant frequency is higher than the resonant frequency, the acoustic resonator filters 50a and 50b may have pass bandwidth formed by the lowest frequency corresponding to the resonant frequency of the at least one shunt acoustic resonator 21, 22, and 23 and the highest frequency corresponding to the antiresonant frequency of the at least one series acoustic resonator 11, 12, 13, and 14. Alternatively, the acoustic resonator filters 50a and 50b may have a stop bandwidth formed by the lowest frequency corresponding to the resonant frequency of at least one series acoustic resonator 11, 12, 13, and 14 and the highest frequency corresponding to the antiresonant frequency of the at least one shunt acoustic resonator 21, 22, and 23.

The pass bandwidth may be widened as a difference between the resonant frequency of the at least one shunt acoustic resonator 21, 22, and 23 and the antiresonant frequency of the at least one series acoustic resonator 11, 12, 13, and 14 increases, and the stop bandwidth may be widened as a difference between the resonant frequency of the at least one series acoustic resonators 11, 12, 13, and 14 and the antiresonant frequency of the at least one shunt acoustic resonators 21, 22 and 23 increases. However, when the difference is too large, the bandwidth may be split and insertion loss and/or return loss of the bandwidth may increase.

When the resonant frequency of the at least one series acoustic resonator 11, 12, 13, and 14 has a predetermined level that is higher than the antiresonant frequency of the at least one shunt acoustic resonator 21, 22, and 23, or when the at least one shunt acoustic resonator 21, 22, and 23 has a predetermined level that is higher than the antiresonant frequency of at least one series acoustic resonator 11, 12, 13, and 14, the bandwidth of the acoustic resonator filters 50a and 50b may be wide and may not split, or loss may be reduced.

In the acoustic resonator, the difference between the resonant frequency and the antiresonant frequency may be determined based on an electromechanical coupling factor kt², which is a physical characteristic of the acoustic resonator, and kt² may be determined based on a size, thickness, and shape of the acoustic resonator. Depending on the implementation, the acoustic resonator filters 50a and 50b may further include passive components to have a frequency characteristic as kt² of some acoustic resonators is adjusted.

Since the bandwidth of the acoustic resonator filters 50a and 50b may have a characteristic proportional to the overall frequency of the bandwidth, the bandwidth may become wider as the overall frequency of the bandwidth increases. However, as the overall frequency of the bandwidth is higher, a wavelength of the RF signal passing through the acoustic resonator filters 50a and 50b may become short. As the wavelength of the RF signal is shorter, energy attenuation compared to a transmission and/or reception distance in a remote transmission/reception process at the antenna may increase. That is, as the overall frequency of the bandwidth of the acoustic resonator filters 50a and 50b is higher, the RF signal passing through the acoustic resonator filters 50a and 50b may need greater power in consideration of energy attenuation in the remote transmission and/or reception process. For example, the RF signal of the 5G communication standard uses a relatively higher frequency compared to other communication standards (e.g., LTE), and may have a higher power (e.g., 26 dBm) than the power (e.g., 23 dBm) of other communication standards (e.g., LTE) to be remotely transmitted through the antenna.

As the power of the RF signal passing through the acoustic resonator filters 50a and 50b increases, the possibility of heat generation according to a piezoelectric operation of each of the at least one shunt acoustic resonator 21, 22, and 23 and the at least one series acoustic resonator 11, 12, 13, and 14 and damage due to heat generation may increase.

When each of the at least one shunt acoustic resonator 21, 22, and 23 and the at least one series acoustic resonator 11, 12, 13, and 14 has a large size or is divided into a plurality of acoustic resonators connected to each other, the acoustic resonator filters 50a and 50b may reduce the possibility of damage due to heat generation. However, the overall size of the acoustic resonator filters 50a and 50b may increase. That is, the possibility of damage due to heat generation of the acoustic resonator filters 50a and 50b and the overall size may be in a trade-off relationship with each other.

The acoustic resonator package, in accordance with one or more embodiments, may include a breakdown voltage shortener 30 to limit a voltage corresponding to the power of the RF signal passing through the acoustic resonator filters 50a and 50b from being higher than the reference voltage.

Accordingly, the power of the RF signal passing through the acoustic resonator filters 50a and 50b may be prevented from becoming too large, so that the possibility of heat generation according to a piezoelectric operation of the at least one shunt acoustic resonator 21, 22, and 23 and the at least each one series acoustic resonator 11, 12, 13, and 14 and damage due to heat generation may decrease. Additionally, since an effect of electrostatic discharge that may occur in the acoustic resonator filters 50a and 50b on the acoustic resonator may be suppressed, the possibility of damage to the resonator due to electrostatic discharge may also be reduced.

For example, the breakdown voltage shortener 30 may be disposed between a node N0 between one of the first and second RF ports P1 and P2 and at least one series acoustic resonator 11, 12, 13, and 14 and the ground. When the voltage between the node N0 and the ground is less than a breakdown voltage, a resistance value of the breakdown voltage shortener 30 may be close to infinity. The voltage between the node N0 and the ground may increase when the power of the RF signal passing through the acoustic resonator filters 50a and 50b increases or electrostatic discharge occurs.

When the voltage between the node N0 and the ground increases to be higher than the breakdown voltage, the resistance value of the breakdown voltage shortener 30 may decrease with a steep slope as the voltage between the node N0 and the ground increases. Accordingly, a current flowing through the breakdown voltage shortener 30 may be formed between the node N0 and the ground and may suppress a voltage increase between the node N0 and the ground. Accordingly, an excessive increase of the power of the RF signal passing through the acoustic resonator filters 50a and 50b and/or the effect of electrostatic discharge on the acoustic resonator filters 50a and 50b may be significantly suppressed.

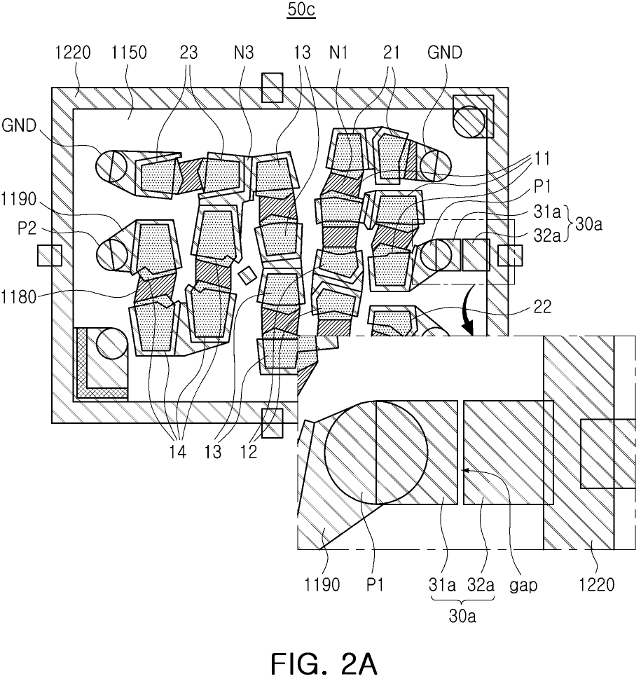

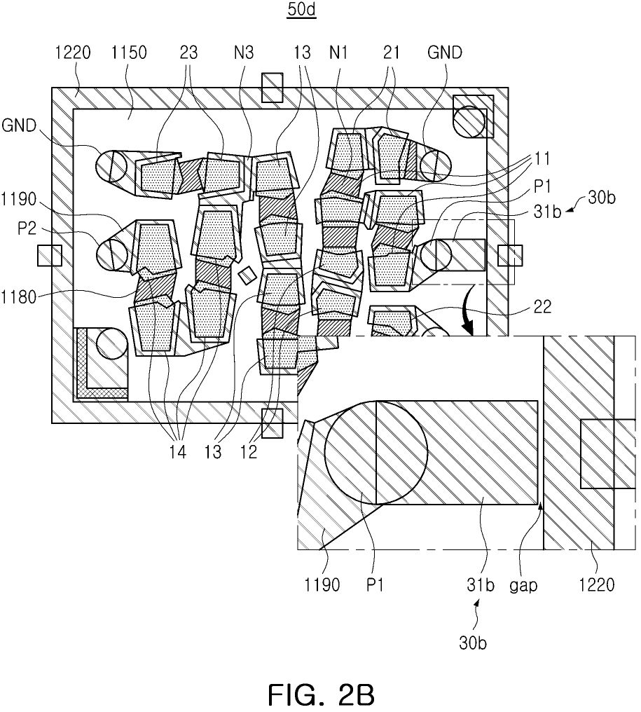

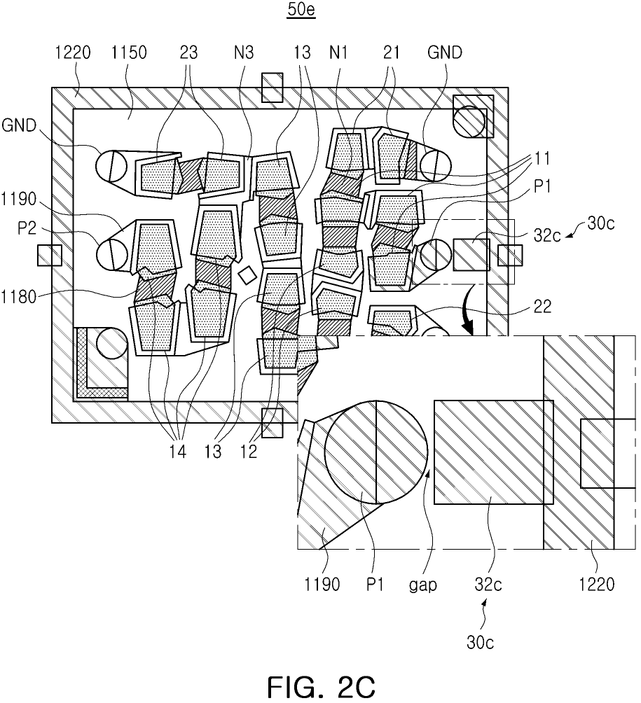

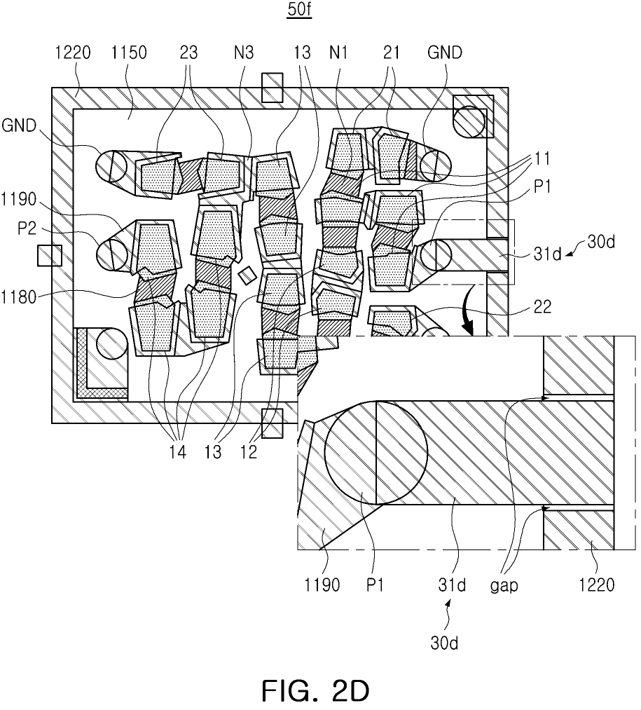

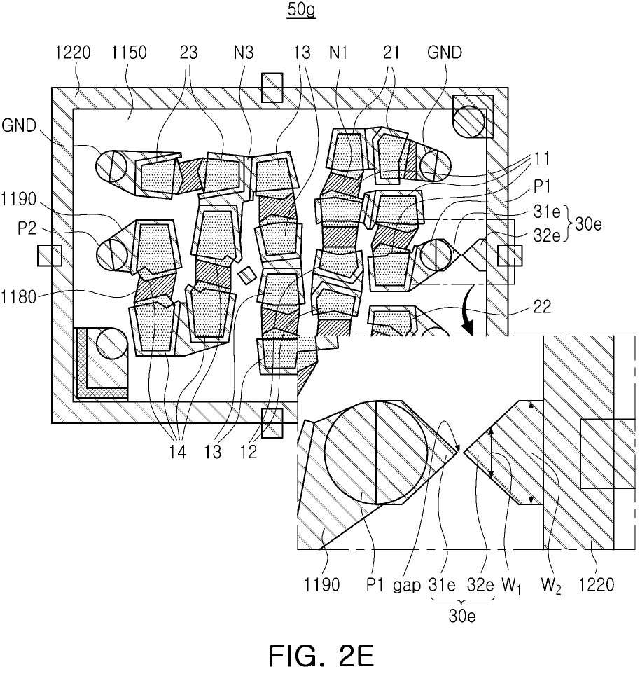

FIGS. 2A to 2E are plan views illustrating various types of breakdown voltage shorteners that may be included in an acoustic resonator package from the perspective of the cap toward the substrate, in accordance with one or more embodiments.

Referring to FIGS. 2A to 2E, acoustic resonator packages 50c, 50d, 50e, 50f, and 50g, in accordance with one or more embodiments, may include various types of breakdown voltage shorteners 30a, 30b, 30c, 30d, and 30e and may include a grounding member 1220.

The grounding member 1220 may be disposed between a substrate and a cap. For example, the grounding member 1220 may provide coupling force between the substrate and the cap. For example, the grounding member 1220 may have a structure in which a plurality of conductive rings is eutectic bonded or may have an anodic bonding structure, may seal a space between the substrate and the cap, and may cut off the space and the outside from each other.

For example, the grounding member 1220 may be disposed closer to the periphery compared to the at least one series acoustic resonator 11, 12, 13, and 14 and the at least one shunt acoustic resonator 21, 22, and 23, may surround at least one series acoustic resonator 11, 12, 13, and 14 and at least one shunt acoustic resonator 21, 22, and 23, and may be electrically connected to ground.

The at least one series acoustic resonator 11, 12, 13, and 14 and the at least one shunt acoustic resonator 21, 22, and 23 may be electrically connected to each other via a first metal layer 1180 or a second metal layer 1190. The first and second metal layers 1180 and 1190 may include the nodes shown in FIGS. 1A and 1B, and may be respectively connected to the first and second electrodes of the acoustic resonator.

The breakdown voltage shorteners 30a, 30b, 30c, 30d, and 30e may provide an air gap that shortens a breakdown voltage between the at least one series acoustic resonator 11, 12, 13, and 14 and the grounding member 1220. Since the breakdown voltage in the air may be 3 kV/mm, the breakdown voltage of the breakdown voltage shorteners 30a, 30b, 30c, 30d, and 30e may be adjusted through a width of the air gap.

Accordingly, since the breakdown voltage shorteners 30a, 30b, 30c, 30d, and 30e may shorten the breakdown voltage between the at least one series acoustic resonator 11, 12, 13, and 14 and the grounding member 1220 even without a separate structure (e.g., a structure including a varistor material, such as ZnO) to shorten the breakdown voltage, cost and/or time to implement the separate structure and secondary influence (e.g., process dispersion increase due to increase in process complexity and/or decrease in process reliability) may be reduced. In an example, the secondary influence may increase as the overall size of the acoustic resonator packages 50c, 50d, 50e, 50f, and 50g decreases, and the overall size may decrease as the wavelength of the RF signal is shorter. The power of the RF signal may increase as the frequency corresponding to the wavelength of the RF signal increases, and the possibility of damage to the acoustic resonator may increase as the power of the RF signal increases. As a result, by implementing an air gap based on the breakdown voltage shortener 30a, 30b, 30c, 30d, and 30e to shorten the breakdown voltage may become more important as the frequency of the RF signal increases or the power of the RF signal increases.

For example, when the width of the air gap is 10 µm, the breakdown voltage of the breakdown voltage shorteners 30a, 30b, 30c, 30d, and 30e may be 30 V and an increase in the voltage of the RF signal passing through at least one series acoustic resonator 11, 12, 13 and 14 may be suppressed when the power of the RF signal is equal to or greater than power corresponding to 30 V.

Since the power of the RF signal may vary according to a communication standard corresponding to the RF signal, the width of the air gap may be appropriately adjusted according to the communication standard. For example, the width of the air gap may be greater than 0 µm and less than or equal to 20 µm.

For example, the breakdown voltage shorteners 30a, 30b, 30c, 30d, and 30e may include portions protruding from the grounding member 1220 or protruding toward the grounding member 1220. For example, the breakdown voltage shorteners 30a, 30b, 30c, 30d, and 30e may include at least one of first portions 31a, 31b, 31d, and 31e protruding toward the grounding member 1220 and second portions 32a, 32c, and 32e protruding from the grounding member 1220. In an example, the air gap may be disposed between the first portions 31a, 31b, 31d, and 31e and the second portions 32a, 32c, and 32e.

For example, the breakdown voltage shorteners 30a, 30b, 30d, and 30e may include first portions 31a, 31b, 31d and 31e protruding from one of the first and second RF ports P1 and P2 toward the grounding member 1220, and the breakdown voltage shortener 30a, 30c, and 30e may further include the second portions 32a, 32c, and 32e protruding from the grounding member 1220 toward one of the first and second RF ports P1 and P2. That is, the breakdown voltage shorteners 30a, 30b, 30c, 30d, and 30e may shorten the breakdown voltage between one of the first and second RF ports P1 and P2 and the grounding member 1220.

In an example, the breakdown voltage of the grounding member 1220 of each of the first and second RF ports P1 and P2 may be different from each other. For example, the breakdown voltage shorteners 30a, 30b, 30c, 30d, and 30e may be directly connected only to the first RF port P1 and may not be directly connected to the second RF port P2. Since the first RF port P1 may be a port to which an RF signal is input, the first RF port P1 may allow an RF signal of greater power to pass therethrough, compared to the second RF port P2. For example, the first RF port P1 may be electrically connected to a power amplifier, and the second RF port P2 may be electrically connected to an antenna.

Referring to FIGS. 2A to 2D, the width of the air gap may be shorter than a length of the air gap perpendicular to the width. Accordingly, the influence of variables (e.g., process dispersion) on the width of the air gap during actual implementation may be further reduced, so that the width of the air gap may be stably implemented.

Alternatively, referring to FIG. 2E, widths W₁ and W₂ of at least one of the first and second portions 31e and 32e may become narrower in a direction toward the air gap. That is, the breakdown voltage shortener 30e may include a portion that protrudes to have the widths W₁ and W₂ that narrow in a direction from the grounding member 1220 to the air gap, or that protrude to have widths W₁ and W₂ that narrow in a direction from the part P1 toward the grounding member 1220.

Accordingly, capacitance formed by the first and second portions 31e and 32e may be reduced, so that an influence of capacitance on at least one series acoustic resonator 11, 12, 13, and 14 and at least one shunt acoustic resonators 21, 22, and 23 may be further reduced.

Referring to FIGS. 2A to 2D, the ground port GND may be disposed at a location different from a location of the grounding member 1220, and may be electrically connected to the at least one shunt acoustic resonator 21, 22, and 23. For example, each of the ground port GND, the first RF port P1, and the second RF port P2 may be in the form of a via that penetrates through one of the substrate and the cap, and may be in the form of wire bonding according to an implementation. Since the ground port GND and the grounding member 1220 may be in an electrically grounded state, the ground port GND and the grounding member 1220 may be electrically connected to each other and may be physically spaced apart from each other.

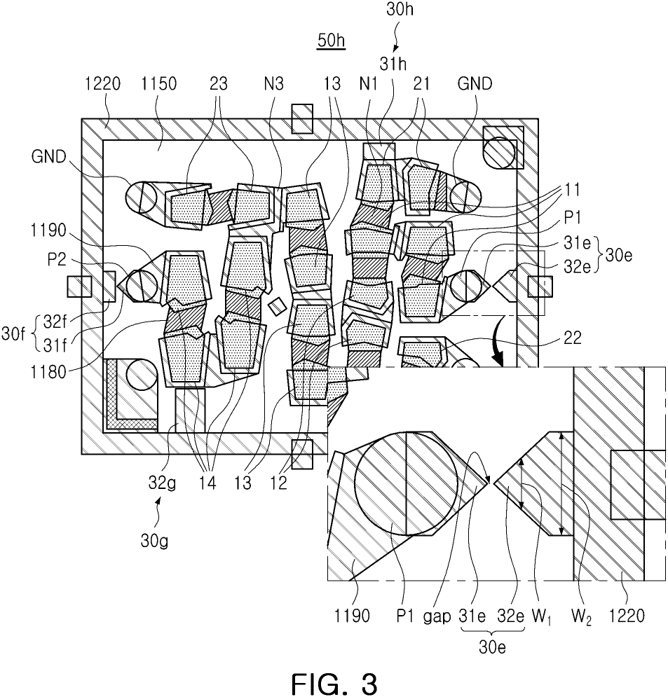

FIG. 3 is a plan view illustrating various positions and numbers of breakdown voltage shorteners that may be included in an acoustic resonator package, in accordance with one or more embodiments.

Referring to FIG. 3, an acoustic resonator package 50h, in accordance with one or more embodiments, may include a plurality of breakdown voltage shorteners 30e, 30f, 30g, and 30h, and, in an example, the plurality of breakdown voltage shorteners 30e, 30f, 30g, and 30h may have different shapes.

For example, the plurality of breakdown voltage shorteners 30e and 30f may be disposed between the first and second RF ports P1 and P2 and the grounding member 1220, and the breakdown voltage shortener 30g may be disposed relatively close to the series acoustic resonator 14, and the breakdown voltage shortener 30h may be disposed relatively close to the node N1.

For example, the shapes of the first and second portions 31f and 32f of the breakdown voltage shortener 30f may be different from the shapes of the first and second portions 31e and 32e of the breakdown voltage shortener 30e, the breakdown voltage shortener 30g may include a second portion 32g, and the breakdown voltage shortener 30h may include a first portion 31h.

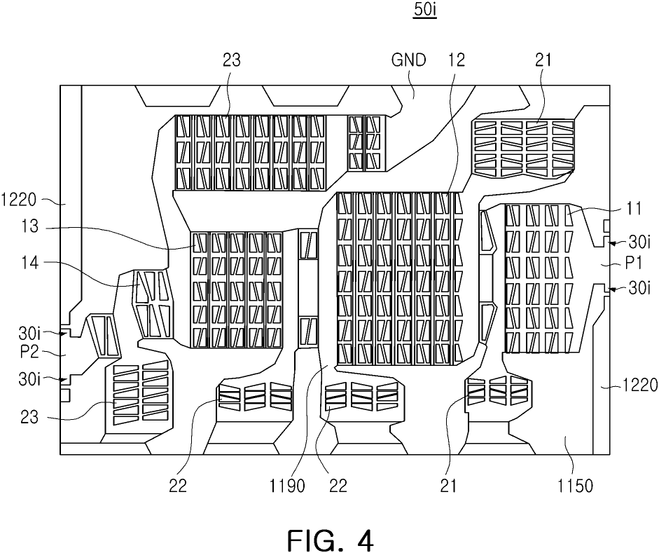

FIG. 4 is a plan view illustrating a large-capacity structure of an acoustic resonator package, in accordance with one or more embodiments.

Referring to FIG. 4, the number of each of at least one series acoustic resonator 11, 12, 13, and 14 and at least one shunt acoustic resonator 21, 22, and 23 of an acoustic resonator package 50i, in accordance with one or more embodiments, may be increased to increase the maximum power. For example, an RF signal remotely transmitted from an antenna of an installation type (e.g., base station) electronic device may have a greater power (e.g., 49 dBm) compared to the power (e.g., 26 dBm) of an RF signal remotely transmitted from an antenna of a mobile communication device, and the installation type electronic device may include the acoustic resonator package 50i, in accordance with one or more embodiments.

The breakdown voltage shortener 30i may increase the breakdown voltage between at least one of the first and second RF ports P1 and P2 and the grounding member 1220 according to the number of at least one series acoustic resonator 11, 12, 13, and 14 and at least one shunt acoustic resonators 21, 22, and 23, and an interval between at least one of the first and second RF ports P1 and P2 and the grounding member 1220 may also be widened. For example, when the power of the RF signal passing through at least one of the first and second RF ports P1 and P2 increases by 23 dB, the breakdown voltage may be increased by about 14.14 times, and the width of the air gap that may be provided by the breakdown voltage shortener 30i may also be widened by about 14.14 times.

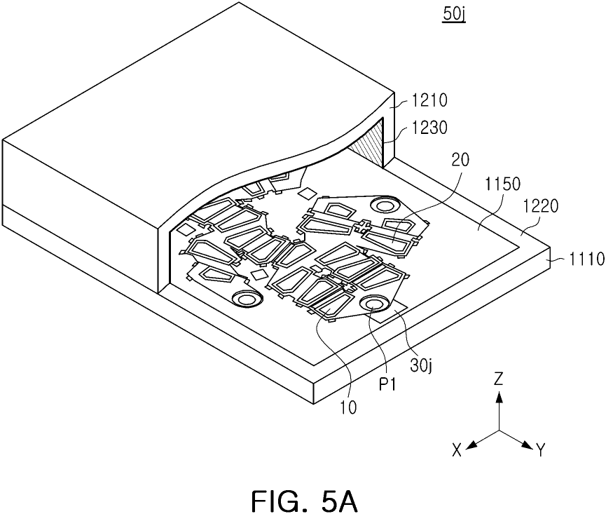

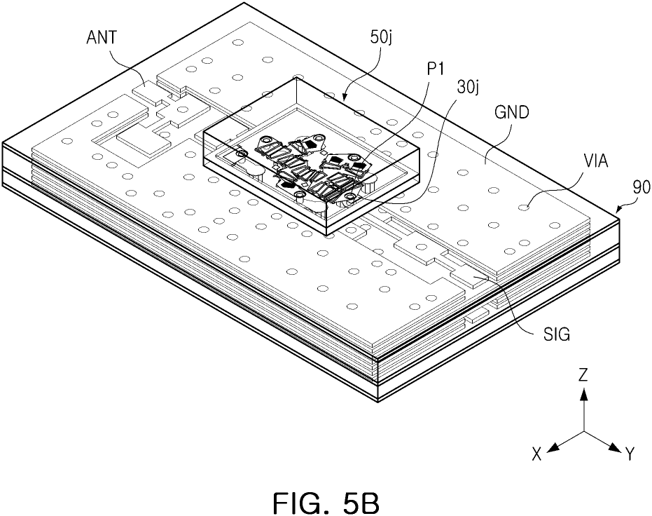

FIGS. 5A and 5B are perspective views illustrating an acoustic resonator package, in accordance with one or more embodiments.

Referring to FIG. 5A, the acoustic resonator package 50j, in accordance with one or more embodiment, may include a substrate 1110 and a cap 1210, the series unit 10 and the shunt unit 20 may be disposed between the substrate 1110 and the cap 1210, and the grounding member 1220 may provide coupling force between the substrate 1110 and the cap 1210.

For example, the cap 1210 may include an insulating material, such as, as only examples, glass or silicon, since the cap 1210 may have a U-shape in terms of a cross-section perpendicular to an X-Y plane, the cap 1210 may have a shape in which an outer portion protrudes downwardly (e.g., a -Z direction), compared with the center of the cap 1210. Depending on the implementation, the cap 1210 may include a shield layer 1230 disposed on the inner surface of the cap 120, and the shield layer 1230 may be connected to the grounding member 1220. The shield layer 1230 may electromagnetically block an internal space surrounded by the cap 1210 and the outside of the cap 1210.

The internal space surrounded by the cap 1210 may be disconnected from the outside of the cap 1210 as the cap 1210 is coupled to the substrate 1110. The grounding member 1220 may couple the cap 1210 and the substrate 1110, and when an additional structure (e.g., a membrane layer 1150, an epoxy resin layer) is disposed between the cap 1210 and the substrate 1110, at least one surface of the grounding member 1220 may be bonded to the additional structure to provide a coupling force between the cap 1210 and the substrate 1110.

The breakdown voltage shortener 30j may be configured to shorten the breakdown voltage between the series unit 10 and/or the first RF port P1 and the grounding member 1220.

Referring to FIG. 5B, the acoustic resonator package 50j, in accordance with one or more embodiments, may be mounted or embedded in the electronic device substrate 90, may receive an RF signal through a power amplifier transmission line SIG of the electronic device substrate 90, may filter the RF signal, and may output the filtered RF signal to an antenna transmission line ANT. The electronic device substrate 90 may be a printed circuit board.

The power amplifier transmission line SIG and the antenna transmission line ANT may be electrically connected to a power amplifier and an antenna, respectively, and may be surrounded by a ground layer of the electronic device substrate 90. The ground layer included in the electronic device substrate 90 may be in the form of a plurality of plates connected to each other through vias VIA, and may be connected to a ground port GND different from the first and second RF ports of the acoustic resonator package 50j.

FIG. 6A is a plan view illustrating a specific structure of an acoustic resonator that may be included in an acoustic resonator package, in accordance with one or more embodiments, FIG. 6B is a cross-sectional view taken along line I-I′ of FIG. 6A, FIG. 6C is a cross-sectional view taken along line II-II′, and FIG. 6D is a cross-sectional view taken along line III-III′ of FIG. 6A.

Referring to FIGS. 6A to 6D, a bulk acoustic resonator 100a may include a support substrate 1110, an insulating layer 1115, a resonant unit 1120, and a hydrophobic layer 1130.

The support substrate 1110 may be a silicon substrate. In an example, a silicon wafer or a silicon on insulator (SOI) type substrate may be used as the support substrate 1110.

The insulating layer 1115 may be provided on an upper surface of the support substrate 1110 to electrically isolate the support substrate 1110 from the resonant unit 1120. Additionally, the insulating layer 1115 may prevent the support substrate 1110 from being etched by an etching gas when a cavity C is formed during the manufacturing process of the bulk acoustic resonator.

In this example, the insulating layer 1115 may be formed of at least one of, but not limited to, silicon dioxide (SiO₂), silicon nitride (Si₃N₄), aluminum oxide (Al₂O₃), and aluminum nitride (AlN), may be formed through any one process among chemical vapor deposition, RF magnetron sputtering, and evaporation.

The support layer 1140 may be formed on the insulating layer 1115, and the support layer 1140 may be disposed in the vicinity of the cavity C and an etch-stop portion 1145 to surround the cavity C and the etch-stop portion 1145.

The cavity C is formed as an empty space and may be formed by removing a portion of a sacrificial layer formed in the process of preparing the support layer 1140, and the support layer 1140 may be formed as a remaining portion of the sacrificial layer.

The support layer 1140 may be formed of a material, such as polysilicon or polymer that is easy to etch. However, the examples are not limited thereto.

The etch-stop portion 1145 may be disposed along a boundary of the cavity C. The etch-stop portion 1145 may be provided to prevent etching from proceeding beyond the cavity region during the cavity C formation process.

A membrane layer 1150 is formed on the support layer 1140 and forms an upper surface of the cavity C. Accordingly, the membrane layer 1150 may also be formed of a material that is not easily removed in the process of forming the cavity C.

For example, when a halide-based etching gas, such as fluorine (F) or chlorine (Cl), is used to remove a portion (e.g., the cavity region) of the support layer 1140, the membrane layer 1150 may be formed of a material with low reactivity with the etching gas. In this example, the membrane layer 1150 may include at least one of silicon dioxide (SiO₂) and silicon nitride (Si₃N₄).

Additionally, the membrane layer 1150 may be formed of a dielectric layer including a material of at least one of magnesium oxide (MgO), zirconium oxide (ZrO₂), aluminum nitride (AlN), lead zirconate titanate (PZT), gallium arsenide (GaAs), hafnium oxide (HfO₂), and aluminum oxide (Al₂O₃), titanium oxide (TiO₂), and zinc oxide (ZnO), or may be formed of a metal layer including a material of at least one of aluminum (Al), nickel (Ni), chromium (Cr), platinum (Pt), gallium (Ga), and hafnium (Hf). However, the configuration of the one or more examples is not limited thereto.

The resonant unit 1120 includes a first electrode 1121, a piezoelectric layer 1123, and a second electrode 1125. In the resonant unit 1120, the first electrode 1121, the piezoelectric layer 1123, and the second electrode 1125 are sequentially stacked from the bottom. Accordingly, in the resonant unit 1120, the piezoelectric layer 1123 may be disposed between the first electrode 1121 and the second electrode 1125.

Since the resonant unit 1120 is formed on the membrane layer 1150, the membrane layer 1150, the first electrode 1121, the piezoelectric layer 1123, and the second electrode 1125 may be sequentially stacked on the support substrate 1110 to eventually form the resonant unit 1120.

The resonant unit 1120 may resonate the piezoelectric layer 1123 according to a signal applied to the first electrode 1121 and the second electrode 1125 to generate a resonant frequency and an antiresonant frequency.

The resonant unit 1120 may include a central portion S in which the first electrode 1121, the piezoelectric layer 1123, and the second electrode 1125 are stacked to be approximately flat, and an extension portion E in which an insertion layer 1170 is interposed between the first electrode 1121 and the piezoelectric layer 1123.

The central portion S is a region disposed in the center of the resonant unit 1120, and the extension portion E is a region disposed along the circumference of the central portion S. Therefore, the extension portion E is a region that extends outwardly from the central portion S, and refers to a region that is formed to have a continuous ring shape along the circumference of the central portion S. However, if necessary, the extension portion E may be formed to have a discontinuous ring shape with a discontinuous partial region.

Accordingly, as shown in FIG. 6B, in a cross-section of the resonant unit 1120 cut to cross the central portion S, the extension portions E may be disposed at both ends of the central portion S. Additionally, the insertion layer 1170 may be disposed on both sides of the extension portion E disposed at both ends of the central portion S.

The insertion layer 1170 may have an inclined surface L having a thickness that increases away from the central portion S.

In the extension portion E, the piezoelectric layer 1123 and the second electrode 1125 may be disposed on the insertion layer 1170. Accordingly, the piezoelectric layer 1123 and the second electrode 1125 located in the extension portion E may have inclined surfaces along the shape of the insertion layer 1170.

In an example, the extension portion E may be defined to be included in the resonant unit 1120, and accordingly, resonance may be achieved in the extension portion E as well. However, the one or more examples are not limited thereto, and, depending on the structure of the extension portion E, resonance may not occur in the extension portion E, but resonance may be made only in the central portion S.

In an example, first electrode 1121 and the second electrode 1125 may be formed of a conductor and may be formed of, as only examples, gold, molybdenum, ruthenium, iridium, aluminum, platinum, titanium, tungsten, palladium, tantalum, chromium, nickel, or a metal including at least one thereof.

In the resonant unit 1120, the first electrode 1121 may be formed to have a larger area than the second electrode 1125, and the first metal layer 1180 may be formed on the first electrode 1121 along an outer portion of the first electrode 1121. Accordingly, the first metal layer 1180 may be disposed to be spaced apart from the second electrode 1125 by a predetermined distance, and may be disposed to surround the resonant unit 1120.

Since the first electrode 1121 may be disposed on the membrane layer 1150, the first electrode 1121 may be formed to be flat as a whole. In an example, since the second electrode 1125 is disposed on the piezoelectric layer 1123, the second electrode 1125 may have a bent portion to correspond to the shape of the piezoelectric layer 1123.

The first electrode 1121 may be implemented as any one of an input electrode and an output electrode to input and output an electrical signal, such as a radio frequency (RF) signal.

The second electrode 1125 may be entirely disposed in the central portion S, and may be partially disposed in the extension portion E. Accordingly, the second electrode 1125 may be divided into a portion disposed on a piezoelectric portion 1123a of the piezoelectric layer 1123 to be described later, and a portion disposed on a bent portion 1123b of the piezoelectric layer 1123.

More specifically, the second electrode 1125 may be disposed to cover the entire piezoelectric portion 1123a and a portion of an inclined portion 11231 of the piezoelectric layer 1123. Accordingly, the second electrode (1125a in FIG. 6D) disposed in the extension portion E may have a smaller area than the inclined surface of the inclined portion 11231, and in the resonant unit 1120, the second electrode 1125 may be formed to have an area smaller than the piezoelectric layer 1123.

Accordingly, as shown in FIG. 6B, in the cross-section in which the resonant unit 1120 is cut to cross the central portion S, an end of the second electrode 1125 may be disposed in the extension portion E. Additionally, the end of the second electrode 1125 disposed in the extension portion E may be disposed such that at least a portion thereof overlaps the insertion layer 1170. In an example, overlapping means that when the second electrode 1125 is projected on a plane on which the insertion layer 1170 is disposed, the shape of the second electrode 1125 projected on the plane overlaps the insertion layer 1170.

The second electrode 1125 may be implemented as any one of an input electrode and an output electrode to input and output an electrical signal, such as a radio frequency (RF) signal. That is, when the first electrode 1121 is implemented as an input electrode, the second electrode 1125 is implemented as an output electrode, and when the first electrode 1121 is implemented as an output electrode, the second electrode 1125 may be implemented as an input electrode.

In an example, as illustrated in FIG. 6D, when the end of the second electrode 1125 is located on the inclined portion 11231 of the piezoelectric layer 1123 to be described later, a local structure of acoustic impedance of the resonant unit 1120 is formed as a sparse/dense/sparse/dense structure from the central portion S, and thus, a reflection interface reflecting a lateral wave toward the inside of the resonant unit 1120 may be increased. Accordingly, since most of lateral waves cannot escape to the outside of the resonant unit 1120 and are reflected into the inside of the resonant unit 1120, the performance of the bulk acoustic resonator may be improved.

The piezoelectric layer 1123 is a portion in which a piezoelectric effect that converts electrical energy into mechanical energy in the form of acoustic waves takes place, and may be formed on the first electrode 1121 and the insertion layer 1170 to be described later.

As a material of the piezoelectric layer 1123, zinc oxide (ZnO), aluminum nitride (AlN), doped aluminum nitride, lead zirconate titanate, quartz, and the like, may be selectively used. The doped aluminum nitride may further include a rare earth metal, a transition metal, or an alkaline earth metal. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). The alkaline earth metal may also include magnesium (Mg). The content of elements doped into aluminum nitride (AlN) may be in the range of 0.1 to 30 at%.

The piezoelectric layer may be implemented by doping aluminum nitride (AlN) with scandium (Sc). In this example, a piezoelectric constant may be increased to increase the Kt² of the bulk acoustic resonator.

The piezoelectric layer 1123 may include a piezoelectric portion 1123a disposed in the central portion S, and a bent portion 1123b disposed in the extension portion E.

The piezoelectric portion 1123a is a portion that is directly stacked on the upper surface of the first electrode 1121. Accordingly, the piezoelectric portion 1123a may be interposed between the first electrode 1121 and the second electrode 1125 to form a flat shape together with the first electrode 1121 and the second electrode 1125.

The bent portion 1123b may be defined as a region that extends outward from the piezoelectric portion 1123a and is located within the extension portion E.

The bent portion 1123b may be disposed on the insertion layer 1170 to be described later, and may be formed such that an upper surface is raised along the shape of the insertion layer 1170. Accordingly, the piezoelectric layer 1123 may be bent at a boundary between the piezoelectric portion 1123a and the bent portion 1123b, and the bent portion 1123b may be raised to correspond to the thickness and shape of the insertion layer 1170.

The bent portion 1123b may be divided into an inclined portion 11231 and an extended portion 11232.

The inclined portion 11231 refers to a portion formed to be inclined along an inclined surface L of the insertion layer 1170, which will be described later. Additionally, the extended portion 11232 refers to a portion that extends outwardly from the inclined portion 11231.

The inclined portion 11231 may be formed parallel to the inclined surface L of the insertion layer 1170, and an inclination angle of the inclined portion 11231 may be formed to be the same as an inclination angle of the inclined surface L of the insertion layer 1170.

The insertion layer 1170 may be disposed along a surface formed by the membrane layer 1150, the first electrode 1121, and the etch-stop portion 1145. Accordingly, the insertion layer 1170 may be partially disposed in the resonant unit 1120, and may be disposed between the first electrode 1121 and the piezoelectric layer 1123.

The insertion layer 1170 may be disposed around the central portion S to support the bent portion 1123b of the piezoelectric layer 1123. Accordingly, the bent portion 1123b of the piezoelectric layer 1123 may be divided into an inclined portion 11231 and an extended portion 11232 according to the shape of the insertion layer 1170.

The insertion layer 1170 may be disposed in a region except for the central portion S. For example, the insertion layer 1170 may be disposed in the entire region except for the central portion S on the support substrate 1110 or may be disposed in a partial region.

The insertion layer 1170 may be formed to have a thickness that increases away from the central portion S. Accordingly, the insertion layer 1170 may be formed to have an inclined surface L in which a side surface disposed adjacent to the central portion S has a constant inclination angle è. The inclination angle è of the inclined surface L may be formed in the range of 5° or more and 70° or less.

In an example, the inclined portion 11231 of the piezoelectric layer 1123 may be formed along the inclined surface L of the insertion layer 1170 and may be formed at the same inclination angle as an inclination angle of the inclined surface L of the insertion layer 1170. Accordingly, the inclination angle of the inclined portion 11231 may be formed in the range of 5° or more and 70° or less, similarly to the inclined surface L of the insertion layer 1170. Of course, this configuration is equally applied to the second electrode 1125 stacked on the inclined surface L of the insertion layer 1170.

The insertion layer 1170 may be formed of a dielectric, such as silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenic (GaAs), hafnium oxide (HfO₂), titanium oxide (TiO₂), or zinc oxide (ZnO), but may be formed of a material different from a material of the piezoelectric layer 1123.

Additionally, the insertion layer 1170 may be formed of a metal material. When the bulk acoustic resonator is used for 5G communications, a lot of heat may be generated in the resonator, and thus, it may be necessary to smoothly dissipate heat generated in the resonant unit 1120. Accordingly, the insertion layer 1170 may be formed of an aluminum alloy material including scandium (Sc).

The resonant unit 1120 may be spaced apart from the support substrate 1110 through, or based on, the cavity C which is formed as an empty space.

The cavity C may be formed by removing a portion of the support layer 1140 by supplying an etching gas (or an etching solution) to an inlet hole (H of FIG. 6A) during a manufacturing process of the bulk acoustic resonator.

Accordingly, the cavity C may be formed as a space in which an upper surface (ceiling surface) and a side surface (wall surface) are formed by the membrane layer 1150 and a bottom surface is formed by the support substrate 1110 or the insulating layer 1115. In an example, the membrane layer 1150 may be formed only on the upper surface (ceiling surface) of the cavity C according to the order of the manufacturing method.

A protective layer 1160 may be disposed along the surface of the bulk acoustic resonator 100a to protect the bulk acoustic resonator 100a from the outside. The protective layer 1160 may be disposed along a surface that is formed by the second electrode 1125 and the bent portion 1123b of the piezoelectric layer 1123.

The protective layer 1160 may be partially removed for frequency control in a final process during the manufacturing process. For example, a thickness of the protective layer 1160 may be adjusted through frequency trimming during a manufacturing process.

Accordingly, the protective layer 1160 may include any one of silicon dioxide (SiO₂), silicon nitride (Si₃N₄), magnesium oxide (MgO), zirconium oxide (ZrO₂), aluminum nitride (AIN), lead zirconate titanate (PZT), gallium arsenic (GaAs), hafnium oxide (HfO₂), aluminum oxide (Al₂O₃), titanium oxide (TiO₂), zinc oxide (ZnO), amorphous silicon (a-Si), polycrystalline silicon (p-Si) suitable for frequency trimming, but is not limited thereto.

The first electrode 1121 and the second electrode 1125 may extend outside the resonant unit 1120. Additionally, a first metal layer 1180 and a second metal layer 1190 may be disposed on an upper surface of the extended portion.

The first metal layer 1180 and the second metal layer 1190 may be formed of a material of any one of gold (Au), a gold-tin (Au-Sn) alloy, copper (Cu), a copper-tin (Cu-Sn) alloy, aluminum (Al), and an aluminum alloy, as only examples. In an example, the aluminum alloy may be an aluminum-germanium (Al—Ge) alloy or an aluminum-scandium (Al—Sc) alloy.

The first metal layer 1180 and the second metal layer 1190 may be implemented as connecting wirings that electrically connect the electrodes 1121 and 1125 of the bulk acoustic resonator on the support substrate 1110 and an electrode of another bulk acoustic resonator disposed adjacent thereto.

At least a portion of the first metal layer 1180 may be in contact with the protective layer 1160 and may be bonded to the first electrode 1121.

Additionally, in the resonant unit 1120, the first electrode 1121 may have a larger area than the second electrode 1125, and the first metal layer 1180 may be formed on a circumferential portion of the first electrode 1121.

Accordingly, the first metal layer 1180 may be disposed along the circumference of the resonant unit 1120 and may be disposed to surround the second electrode 1125. However, the examples are not limited thereto.

In the bulk acoustic resonator, the hydrophobic layer 1130 may be disposed on a surface of the protective layer 1160 and an inner wall of the cavity C. Since the hydrophobic layer 1130 may suppress the adsorption of water and hydroxyl groups (OH groups), frequency fluctuations may be minimized, and thus, the resonator performance may be uniformly maintained.

The hydrophobic layer 1130 may be formed of a self-assembled monolayer (SAM) forming material rather than a polymer. When the hydrophobic layer 1130 is formed of a polymer, a mass of the polymer may affect the resonant unit 1120. However, in the bulk acoustic resonator, since the hydrophobic layer 1130 is formed of a self-assembled monolayer, fluctuations in the resonant frequency of the bulk acoustic resonator may be minimized. Additionally, a thickness of the hydrophobic layer 1130 according to the position in the cavity C may be uniformly formed.

The hydrophobic layer 1130 may be formed by vapor-depositing a precursor having hydrophobicity. At this time, the hydrophobic layer 1130 may be deposited as a monolayer having a thickness of 100 Å or less (e.g., several Å to several tens of Å). A precursor material that may have hydrophobicity may be a material in which a contact angle with water after deposition is 90 degrees or more. For example, the hydrophobic layer 1130 may contain a fluorine (F) component and may include fluorine (F) and silicon (Si). Specifically, fluorocarbon having a silicon head may be used, but is not limited thereto.

In an example, in order to improve adhesion between the self-assembled monolayer constituting the hydrophobic layer 1130 and the protective layer 1160, a bonding layer (not shown) may be formed on the surface of the protective layer, before forming the hydrophobic layer 1130.

The bonding layer may be formed by vapor-depositing a precursor having a hydrophobic functional group on the surface of the protective layer 1160.

A precursor used for deposition of the bonding layer may be hydrocarbon having a silicon head or siloxane having a silicon head, but is not limited thereto.

Since the hydrophobic layer 1130 may be formed after the first metal layer 1180 and the second metal layer 1190 are formed, the hydrophobic layer 1130 may be formed along the surfaces of the protective layer 1160, the first metal layer 1180, and the second metal layer 1190.

In the drawings, an example in which the hydrophobic layer 1130 is not disposed on the surfaces of the first metal layer 1180 and the second metal layer 1190 is illustrated. However, the one or more examples are not limited thereto, and the hydrophobic layer 1130 may be disposed on the first metal layer 1180 and the second metal layer 1190 as necessary.

Additionally, the hydrophobic layer 1130 may also be disposed on an inner surface of the cavity C, as well as on an upper surface of the protective layer 1160.

The hydrophobic layer 1130 formed in the cavity C may be formed on the entire inner wall forming the cavity C. Accordingly, the hydrophobic layer 1130 may also be formed on a lower surface of the membrane layer 1150 forming a lower surface of the resonant unit 1120. In this case, adsorption of a hydroxyl group to a lower portion of the resonant unit 1120 may be suppressed.

Adsorption of the hydroxyl group may occur not only in the protective layer 1160 but also in the cavity C. Therefore, in order to minimize mass loading and consequent frequency drop due to adsorption of the hydroxyl group, it is preferable to block adsorption of the hydroxyl group not only in the protective layer 1160 but also in the upper surface of the cavity C, which is a lower surface of the resonant unit (the lower surface of the membrane layer).

Additionally, when the hydrophobic layer 1130 is formed on an upper and/or lower surface or a side surface of the cavity C, an effect of suppressing an occurrence of a phenomenon (stiction phenomenon) in which the resonant unit 1120 is attached to the insulating layer 1115 due to surface tension during a wet process or a cleaning process after the cavity C is formed may also be provided.

An example of forming the hydrophobic layer 1130 on the entire inner wall of the cavity C is provided as an example. However, the one or more examples are not limited thereto, and various modifications may be made, such as forming the hydrophobic layer 1130 only on the upper surface of the cavity C or forming the hydrophobic layer 1130 only in at least a portion of the lower surface or the side surface.

In an example, the thickness T of the bulk acoustic resonator 100a may be determined based on an implemented resonant frequency and/or antiresonant frequency. For example, the thickness T may be measured by analysis using at least one of a transmission electron microscopy (TEM), an atomic force microscope (AFM), a scanning electron microscope (SEM), an optical microscope, and a surface profiler.

FIGS. 6E and 6F are cross-sectional views illustrating a structure for electrically connecting the inside and the outside of an acoustic resonator package according to an exemplary embodiment in the present disclosure.

Referring to FIGS. 6E and 6F, bulk acoustic resonators 100f and 100g may further include at least one of a hydrophobic layer 1130, a bump 1310, a connection pattern 1320, and a hydrophobic layer 1330.

The hydrophobic layer 1130 may be disposed between the resonant unit 1120 and the cap 1210 and may have a characteristic relatively close to hydrophobicity than the cap 1210. Accordingly, adsorption of organic matter, moisture, and the like, that may occur in the process of forming the grounding member 1220 to the resonant unit 1120 may be reduced, thereby further improving the characteristics of the resonant unit 1120. For example, the hydrophobic layer 1130 may be formed on the upper surface of the resonant unit 1120.

Referring to FIG. 6E, at least a portion of the connection pattern 1320 may pass through the substrate 1110, may be electrically connected to at least one of the first and second electrodes 1121 and 1125, and may be in contact with the hydrophobic layer 1330. Accordingly, the resonant unit 1120 may be electrically connected to the outside of the bulk acoustic resonator package 100f.

The hydrophobic layer 1330 may be disposed on a surface (e.g., a lower surface) opposite to the surface (e.g., an upper surface) facing the cap 1210 in the substrate 1110 and may have a characteristic relatively close to hydrophobicity than the substrate 1110. Accordingly, adsorption of organic matter, moisture, and the like, that may occur in the process of forming the grounding member 1220 to the connection pattern 1320 may be reduced, thereby further reducing transmission loss in the connection pattern 1320.

Referring to FIG. 6F, at least a portion of the connection pattern 1320 may pass through the cap 1210, may be electrically connected to at least one of the first and second electrodes 1121 and 1125, and may be in contact with the hydrophobic layer 1330. Accordingly, the resonant unit 1120 may be electrically connected to the outside of the bulk acoustic resonator package 100g.

The hydrophobic layer 1330 may be disposed on a surface (e.g., an upper surface) opposite to the surface (e.g., a lower surface) facing the substrate 1110 in the cap 1210 and may have a characteristic relatively close to hydrophobicity than the cap 1210. Accordingly, adsorption of organic matter, moisture, and the like, that may occur in the process of forming the grounding member 1220 to the connection pattern 1320 may be reduced, thereby further reducing transmission loss in the connection pattern 1320.

In an example, the connection pattern 1320 may be formed through a process of depositing, applying, or charging a conductive metal (e.g., gold, copper, titanium (Ti)-copper (Cu) alloy), and the like,) on a side wall of a hole formed in a portion of the substrate 1110 and/or the cap 1210.

In an example, a process of forming a hole in a portion of the substrate 1110 and/or the cap 1210 may be omitted. For example, the resonant unit 1120 may be provided with an electrical connection path through wire bonding.

The bump 1310 may have a structure supporting the bulk acoustic resonators 100f and 100g so that the bulk acoustic resonators 100f and 100g may be mounted on a lower external PCB. For example, a portion of the connection pattern 1320 may have a pad shape in contact with the bump 1310.

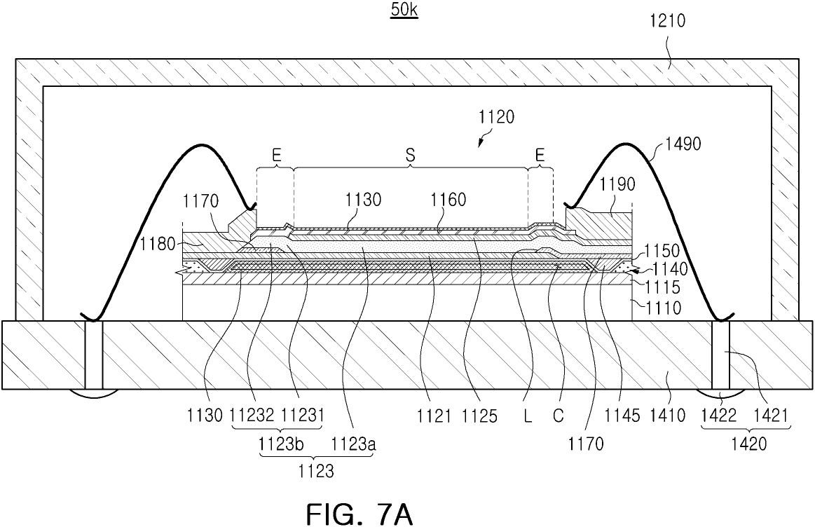

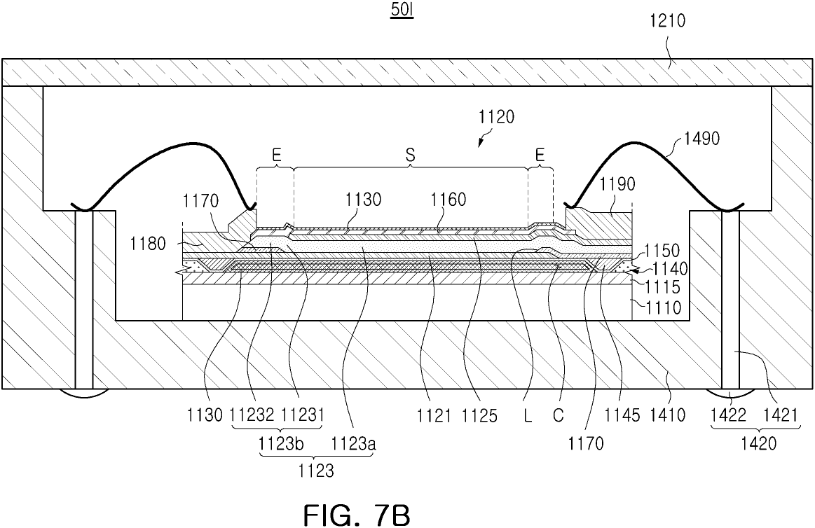

FIGS. 7A and 7B are cross-sectional views illustrating a bonding structure between a cap and a base substrate of an acoustic resonator package, in accordance with one or more embodiments.

Referring to FIGS. 7A and 7B, the acoustic resonator packages 50k and 50l, in accordance with one or more embodiments, may include the resonant unit 1120 disposed between the substrate 1110 and the cap 1210, the substrate 1110 may be disposed on the base substrate 1410, and the base substrate 1410 may be bonded to the cap 1210.

Since an area of the base substrate 1410 may be equal to or greater than an area of the substrate 1110, the base substrate 1410 may provide a larger area in which the resonant unit 1120 is disposed compared to the substrate 1110. For example, the acoustic resonator packages 50k and 50l may be more efficient because the number of the resonant units 1120 disposed on the base substrate 1410 increases, so that it is more efficient to implement the large-capacity structure shown in FIG. 4.

Since the cap 1210 may be bonded to the base substrate 1410, a horizontal area of the cap 1210 may also be increased. For example, since the base substrate 1410 may contain a ceramic material, the base substrate 1410 may be implemented in a method different from a wafer level package (WLP) method, and a bonding structure (e.g., an adhesive polymer) between the cap 1210 and the base substrate 1410 may also be different from a structure of the grounding member of the present disclosure (e.g., a eutectic bonding structure or an anodic bonding structure). For example, the grounding member may be disposed in an area overlapping an area surrounded by the cap 1210 in a vertical direction and may not provide a bonding force to the cap 1210.

For example, the base substrate 1410 may be thicker than the substrate 1110 to stably have a large horizontal area, the cap 1210 may contain a metal material to stably have a large horizontal area, a thermosetting resin, such as an epoxy resin, may bond the base substrate 1410 and the substrate 1110 to each other, but is not limited thereto. A material contained in the base substrate 1410 is not limited to a ceramic material, and may contain the same material as a material contained in the substrate 1110.

Referring to FIGS. 7A and 7B, acoustic resonator packages 50k and 50l, in accordance with one or more embodiments, may include at least one of a base substrate 1410, a connection pattern 1420, and a bonding wire 1490.

The connection pattern 1420 may include a through via 1421 that vertically passes through the base substrate 1410 and a pad 1422 disposed on a lower surface of the base substrate 1410 and may be formed in the same manner as that of the connection pattern illustrated in FIGS. 6E and 6F, but is not limited thereto.

The bonding wire 1490 may connect the connection pattern 1420 and the first metal layer 1180 or the second metal layer 1190 to each other and may contain the same metal material as the metal material contained in the first and second metal layers 1180 and 1190, but is not limited thereto.

Referring to FIG. 7B, the substrate 1110 and/or the resonant unit 1120 may be disposed in a recessed space of the base substrate 1410, and thus may be surrounded by the base substrate 1410. For example, the cap 1210 may have a plate shape having a constant thickness.

The acoustic resonator package in accordance with one or more embodiments may effectively reduce the possibility of damage to the acoustic resonator due to an excessive increase in power of an RF signal passing therethrough, or may effectively reduce the possibility of damage to the acoustic resonator due to electrostatic discharge.

The effectiveness of the effects of the acoustic resonator package in accordance with one or more embodiments described above may be increased as the size of the acoustic resonator package decreases overall or a frequency of the RF signal increases.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. An acoustic resonator package, comprising:
a substrate;
a cap;
a plurality of acoustic resonators disposed between the substrate and the cap, and configured to be electrically connected to each other;
a grounding member disposed between the substrate and the cap; and
a breakdown voltage shortener configured to provide an air gap to shorten a breakdown voltage between one of the plurality of acoustic resonators and the grounding member.

2. The acoustic resonator package of claim 1, wherein a width of the air gap is greater than 0 µm and less than or equal to 20 µm.

3. The acoustic resonator package of claim 1, wherein:
the breakdown voltage shortener comprises a portion that protrudes from the grounding member or a portion that protrudes toward the grounding member, and
a width of the air gap is narrower than a length of the air gap perpendicular to the width.

4. The acoustic resonator package of claim 1, wherein:
the breakdown voltage shortener comprises a first portion that protrudes toward the grounding member and a second portion that protrudes from the grounding member, and
the air gap is located between the first portion and the second portion.

5. The acoustic resonator package of claim 1, wherein the grounding member is configured to provide a coupling force between the substrate and the cap.

6. The acoustic resonator package of claim 1, wherein an outer portion of the substrate is located closer to the grounding member than to the plurality of acoustic resonators.

7. The acoustic resonator package of claim 1, wherein:
the grounding member is configured to surround the plurality of acoustic resonators, and
another of the plurality of acoustic resonators is electrically connected to a ground port disposed at a position that is different from a position of the grounding member.

8. The acoustic resonator package of claim 1, wherein:
each of the plurality of acoustic resonators is a bulk acoustic resonator which has a structure in which a first electrode, a piezoelectric layer, and a second electrode are stacked in a direction in which the substrate and the cap face each other, and
the plurality of acoustic resonators are configured to form a frequency bandwidth of a filter.

9. The acoustic resonator package of claim 1, further comprising:
a first radio frequency (RF) port and a second RF port electrically connected to the one of the plurality of acoustic resonators to pass an external RF signal of the acoustic resonator package between at least one of the plurality of acoustic resonators,
wherein the breakdown voltage shortener is configured to shorten a breakdown voltage between one of the first RF port and the second RF port and the grounding member.

10. The acoustic resonator package of claim 9, wherein the breakdown voltages of the first RF port and the second RF port for the grounding member are different from each other.

11. The acoustic resonator package of claim 9, wherein the breakdown voltage shortener comprises a first portion that protrudes from one of the first RF port and the second RF port toward the grounding member.

12. The acoustic resonator package of claim 11, wherein:
the breakdown voltage shortener further comprises a second portion that protrudes from the grounding member toward one of the first RF port and the second RF port, and
a width of at least a portion of at least one of the first portion and the second portion becomes narrower in a direction toward the air gap.

13. An acoustic resonator package, comprising:
a substrate;
a cap;
a plurality of acoustic resonators disposed between the substrate and the cap and configured to be electrically connected to each other;
a grounding member disposed between the substrate and the cap; and
a breakdown voltage shortener configured to shorten a breakdown voltage between one of the plurality of acoustic resonators and the grounding member;
wherein the breakdown voltage shortener comprises a portion that protrudes to have a width that narrows in a direction extending from the grounding member, or that protrudes to have a width that narrows in a direction toward the grounding member.

14. The acoustic resonator package of claim 13, further comprising:
a first radio frequency (RF) port and a second RF port that are electrically connected to one of the plurality of acoustic resonators to pass an external RF signal of the acoustic resonator package between at least one of the plurality of acoustic resonators,
wherein the breakdown voltage shortener comprises the portion that protrudes to have a width that narrows in the direction from the grounding member, or a portion that protrudes to have a width that narrows in a direction from one of the first RF port and the second RF port to the grounding member.

15. The acoustic resonator package of claim 14, wherein the breakdown voltages of the first RF port and the second RF port for the grounding member are different from each other.

16. The acoustic resonator package of claim 13, wherein:
an outer portion of the substrate is located closer to the grounding member than to the plurality of acoustic resonators, and
another of the plurality of acoustic resonators is electrically connected to a ground port disposed at a position that is different from a position of the grounding member.

17. The acoustic resonator package of claim 13, wherein the grounding member is configured to provide a coupling force between the substrate and the cap.

18. The acoustic resonator package of claim 13, wherein:
each of the plurality of acoustic resonators is a bulk acoustic resonator having a structure in which a first electrode, a piezoelectric layer, and a second electrode are stacked in a direction in which the substrate and the cap face each other, and
the plurality of acoustic resonators are configured to form a frequency bandwidth of a filter.

19. An acoustic resonator package, comprising:
a substrate;
a cap;
a plurality of acoustic resonators disposed between the substrate and the cap, and configured to be electrically connected to each other;
a grounding member, comprising a plurality of conductive rings, and disposed between the substrate and the cap; and
a breakdown voltage shortener configured to shorten a breakdown voltage between one of the plurality of acoustic resonators and the grounding member;
wherein the breakdown voltage shortener is disposed adjacent to the grounding member.

20. The acoustic resonator package of claim 19, wherein the breakdown voltage shortener comprises a first portion that extends in a direction from one of a first RF port and a second RF port to the grounding member, and a second portion that extends in a direction from the grounding member to the one of the first RF port and the second RF port.
